(19) United States
(12) Patent Application Publication
(10) Pub. No.: US 2025/0024607 A1
(43) Pub. Date: Jan. 16, 2025

(54) CIRCUIT BOARD AND DISPLAY MODULE

(71) Applicant: WUHAN CHINA STAR OPTOELECTRONICS SEMICONDUCTOR DISPLAY TECHNOLOGY CO., LTD., Wuhan (CN)

(72) Inventor: Rong GUO, Wuhan (CN)

(21) Appl. No.: 17/770,334

(22) PCT Filed: Mar. 28, 2022
(86) PCT No.: PCT/CN2022/083321

§ 371 Date: Apr. 20, 2022

(30) Foreign Application Priority Data
Mar. 18, 2022 (CN) 202210270819.4

(51) Int. Cl. H05K 1/14; H05K 1/03; H05K 1/11

(52) U.S. Cl. CPC H05K 1/147; H05K 1/032; H05K 1/0366; H05K 1/115; H05K 1/118; H05K 2201/09563; H05K 2201/10128; H05K 2201/1034

(57) ABSTRACT

A circuit board and a display module are disclosed. The display module includes a display panel and the circuit board. The circuit board includes a hard first board body and a soft second board body. By integrating a flexible circuit layer into a preparation process of the first board body, a combination of the first board body and the second board body is realized. This avoids a late binding process or an access of electrical connectors, so that a product becomes lighter and thinner and a connection stability is enhanced.

### FIELD OF INVENTION

The present application relates to the field of display technologies, and more particularly to a circuit board and a display module.

### BACKGROUND OF INVENTION

With the popularization of OLED technology, consumers have higher and higher requirements for an operating frequency, resolution, and thinness of OLED screens. For conventional designs, a mid-size display panel side and a printed circuit board side need to be interconnected with a flexible circuit board. The flexible circuit board side and the printed circuit board side are usually connected by means of electrical connectors or gold finger binding. However, a height of the electrical connectors is limited, and gold fingers have high requirements on a pad spacing and a binding process on a side of the printed circuit board, making it difficult to achieve product thinning and product quality stability.

### Technical Problem

The printed circuit board and the flexible circuit board in the prior art are prepared independently respectively, and a connection between the two circuit boards needs to be realized by an electrical connector or a gold finger binding process during later assembly. The binding process requirements are higher and the binding process is more complicated, which affects a product yield, or the use of electrical connectors results in an impact of a product space where the circuit board is used. There is a need to provide a new way to connect circuit boards.

### SUMMARY OF INVENTION

The embodiments of the present application provide a circuit board, which incorporates a flexible circuit board into a manufacturing process of a printed circuit board. Part of circuit layers of the flexible circuit board are embedded in an interlayer structure of the printed circuit board and pressed together to realize a combination of the printed circuit board and the flexible circuit board. This avoids a need for a binding process or access of electrical connectors in a later stage, so as to make the product lighter and thinner and enhance stability of a circuit connection.

In order to solve the above technical problems, the present invention provides a circuit board comprising a first board body and a second board body combined with the first board body, wherein the first board body is a rigid board body, the second board body is a flexible board body, the first board body comprises a flexible circuit layer fixedly arranged in the first board body, and the flexible circuit layer comprises a flexible substrate and a metal wiring layer disposed on at least one side of the flexible substrate: wherein the flexible circuit layer is electrically connected to the metal wiring layer of the first board body and extends to an outside of the first board body, and a part of the flexible circuit layer outside the first board body is any functional layer of the second board body.

According to an embodiment of the present application, the first board body comprises a multi-layer interlayer substrate and the metal wiring layer located on the multi-layer interlayer substrate, and the multi-layer interlayer substrate comprises a rigid board and at least one layer of the flexible circuit layer.

According to an embodiment of the present application, an edge of the flexible circuit layer located in the first board body is arranged flush with an edge of the first board body or is arranged inwardly in the first board body and maintains a preset distance from the edge of the first board body.

According to an embodiment of the present application, in a thickness direction of the first board body, the flexible circuit layer is relatively located in a middle position of the first board body.

According to an embodiment of the present application, a via hole is formed on the multi-layer interlayer substrate, and metal wiring layers located in different layers are communicated through the via hole.

According to an embodiment of the present application, in the multi-layer interlayer substrate, a material of the rigid board is one or a combination of two or more of a phenolic resin, a glass fiber, and an epoxy resin: a substrate material of the flexible circuit layer is a polyimide, a polyester film, a polytetrafluoroethylene, or a polyamide fiber.

According to an embodiment of the present application, the second board body comprises at least one layer of the flexible circuit layer, one end of the flexible circuit layer is set as a pressing part, and the pressing part of the flexible circuit layer is fixedly arranged in the first board body.

According to an embodiment of the present application, an opposite end of the flexible circuit layer where the pressing part is located is set as a binding part, and the binding part of the flexible circuit layer is suspended before binding an external device.

According to an embodiment of the present application, the second board body comprises two or more sub-boards arranged at intervals along a same direction, pressing parts of the sub-boards are connected to form a board, and binding parts of the sub-boards are arranged independently of each other.

The present invention further provides a display module, the display module comprises a display panel and a circuit board, wherein the circuit board comprises a first board body and a second board body combined with the first board body, wherein the first board body is a rigid board body, the second board body is a flexible board body, the first board body comprises a flexible circuit layer fixedly arranged in the first board body, and the flexible circuit layer comprises a flexible substrate and a metal wiring layer disposed on at least one side of the flexible substrate:

wherein the flexible circuit layer is electrically connected to the metal wiring layer of the first board body and extends to an outside of the first board body, a part of the flexible circuit layer outside the first board body is any functional layer of the second board body, a border area of the display panel is provided with a binding terminal, and a binding part of the flexible circuit layer is fixed and electrically connected to the binding terminal of the display panel.

According to an embodiment of the present application, the first board body comprises a multi-layer interlayer substrate and the metal wiring layer located on the multi-layer interlayer substrate, and the multi-layer interlayer substrate comprises a rigid board and at least one layer of the flexible circuit layer.

According to an embodiment of the present application, an edge of the flexible circuit layer located in the first board body is arranged flush with an edge of the first board body or is arranged inwardly in the first board body and maintains a preset distance from the edge of the first board body.

According to an embodiment of the present application, in a thickness direction of the first board body, the flexible circuit layer is relatively located in a middle position of the first board body.

According to an embodiment of the present application, a via hole is formed on the multi-layer interlayer substrate, wherein metal wiring layers located in different layers are communicated through the via hole.

According to an embodiment of the present application, the via hole is filled with a metal conductive material, and the metal conductive material comprises any one of copper, aluminum, nickel, and tin.

According to an embodiment of the present application, in the multi-layer interlayer substrate, a material of the rigid board is one or a combination of two or more of a phenolic resin, a glass fiber, and an epoxy resin; a substrate material of the flexible circuit layer is a polyimide, a polyester film, a polytetrafluoroethylene, or a polyamide fiber.

According to an embodiment of the present application, the second board body comprises at least one layer of the flexible circuit layer, one end of the flexible circuit layer is set as a pressing part, and the pressing part of the flexible circuit layer is fixedly arranged in the first board body.

According to an embodiment of the present application, an opposite end of the flexible circuit layer where the pressing part is located is set as a binding part, and the binding part of the flexible circuit layer is suspended before binding an external device.

According to an embodiment of the present application, the second board body comprises two or more sub-boards arranged at intervals along a same direction, pressing parts of the sub-boards are connected to form a board, and binding parts of the sub-boards are arranged independently of each other.

According to an embodiment of the present application, a material of the metal wiring layer is tin, copper, chromium, palladium, nickel, gold, aluminum, or one of alloys of above metal materials.

### Beneficial Effect:

The beneficial effects of the embodiments of the present disclosure: compared with the prior art, the circuit board provided by the present invention integrates the flexible circuit board into the preparation process of the printed circuit board. Part of the circuit layers of the flexible circuit board are embedded in the interlayer structure of the printed circuit board and pressed together to realize the combination of the printed circuit board and the flexible circuit board. This avoids the late binding process or the access of electrical connectors, so that the product becomes lighter and thinner and the connection stability is enhanced.

### DESCRIPTION OF DRAWINGS

In order to illustrate the embodiments or technical solutions in the prior art more clearly, the following briefly introduces the accompanying drawings that are required to be used in the description of the embodiments or the prior art. Obviously, the drawings in the following description are only some of the disclosed embodiments. For those of ordinary skill in the art, other drawings can also be obtained from these drawings without creative effort.

FIG. 1 is a schematic structural diagram of a circuit board according to the present invention.

FIG. 2 is a schematic cross-sectional view of a first circuit board along A-A direction according to an embodiment of the present application.

FIG. 3 is a schematic cross-sectional view of a second circuit board along the A-A direction according to an embodiment of the present application.

FIG. 4 is a schematic cross-sectional view of a third circuit board along the A-A direction according to an embodiment of the present application.

FIG. 5 is a schematic structural diagram of a display module according to an embodiment of the present application.

### DETAILED DESCRIPTION OF PREFERRED EMBODIMENTS

The following descriptions of the various embodiments refer to the accompanying drawings to illustrate specific embodiments in which the present disclosure may be practiced. The directional terms mentioned in this disclosure, such as “up”, “down”, “front”, “rear”, “left”, “right”, “inner”, “outer”, “side”, etc., only refer to the orientation of the attached drawings. Accordingly, the directional terms used are used to describe and understand the present disclosure, rather than to limit the present disclosure. In the figures, structurally similar elements are denoted by the same reference numerals.

The present disclosure will be further described below in conjunction with the accompanying drawings and specific embodiments:

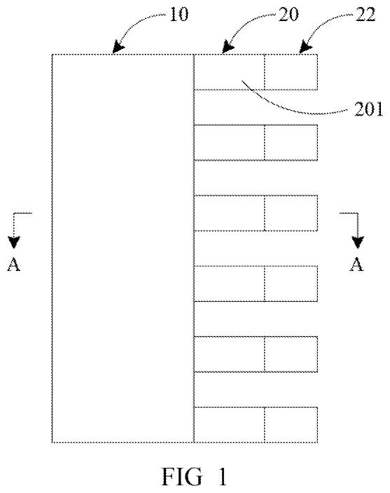

Refer to FIG. 1, which is a schematic structural diagram of a circuit board according to an embodiment of the present application. The circuit board provided in the embodiment of the present application includes at least a first board body 10 and a second board body 20 connected to the first board body 10. The first board body 10 is a rigid printed circuit board (PCB), and the second board body 20 is a flexible printed circuit (FPC).

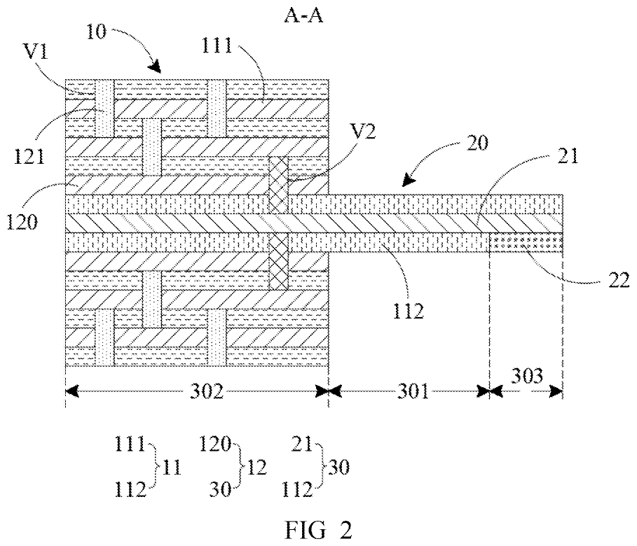

Refer to FIG. 2, which is a schematic cross-sectional view of a first circuit board along A-A direction according to an embodiment of the present application. The first board body 10 includes a multi-layer metal wiring layer 11 and a multi-layer interlayer substrate 12 supporting the metal wiring layer 11. The interlayer substrate 12 of the first board body 10 includes a rigid board 120. The second board body 20 includes at least one metal wiring layer 11 and a flexible substrate 21 supporting the metal wiring layer 11. A flexible circuit layer 30 is further provided on the first board body 10 and/or the second board body 20. That is, the flexible circuit layer 30 has an electrical connection and a positional correspondence on the first board body 10 and the second board body 20. The flexible circuit layer 30 may be integrally provided with the first board body 10 and extended out of the first board body 10, and then connected to the second board body 20. Similarly, the flexible circuit layer 30 may also be integrally provided with the second board body 20 and extended out of the second board body 20, and then connected with the first board body 10, which is not limited here. Compared with the combination of the flexible circuit board and the rigid circuit board through external binding of the circuit board or through electrical connectors, by prefabricating the flexible circuit layer 30 in the rigid circuit board to realize the combination with the flexible circuit board, it has a more stable electrical function. This can also reduce a volume increase of the circuit board caused by the arrangement of the electrical connectors.

Further, the flexible circuit layer 30 includes a flexible substrate 21 and a metal wiring layer 11 disposed on at least one side of the flexible substrate. Part of the flexible circuit layer 30 is fixedly disposed in the first board body 10 and is electrically connected with the metal wiring layers 11 of different layers in the first board body 10. The second board body 20 includes multiple functional layers. The functional layer refers to a single layer or a superimposed circuit layer of two or more layers. The flexible substrate 21 is disposed between circuit layers of different layers. The part of the flexible circuit layer 30 outside the first board body 10 is any functional layer of the second board body 20.

A material of the flexible substrate 21 of the flexible circuit layer 30 is a combination of one or more flexible materials of polyimide, polyester film, polytetrafluoroethylene, or polyamide fiber.

The material of a rigid board 120 in the first board body 10 is one or a combination of two or more materials selected from phenolic resin, glass fiber, and epoxy resin.

Specifically, the first board body 10 includes a multi-layer interlayer substrate 12 and the metal wiring layer 11 located on the interlayer substrate 12. The interlayer substrate 12 includes the rigid board 120 and at least one layer of the flexible circuit layer 30.

As shown in FIG. 2, the metal wiring layer 11 includes a first metal wiring layer 111 and a second metal wiring layer 112. The first metal wiring layer 111 is disposed on the side of the rigid board 120 away from the flexible substrate 21. The second metal wiring layer 112 is disposed on the flexible substrate 21 and located between the flexible substrate 21 and the rigid board 120.

In the embodiment of the present application, a material of the metal wiring layer 11 may be tin (Sn), copper (Cu), chromium (Cr), palladium (Pd), nickel (Ni), gold (Au), aluminum (Al) or one of the alloys of the above metal materials.

Further, an edge of the flexible circuit layer 30 in the first board body 10 is disposed flush with an edge of the first board body 10, or is arranged inwardly in the first board body 10 and maintains a preset distance from the edge of the first board body 10.

In one embodiment, as shown in FIG. 2, the edge of the flexible circuit layer 30 in the first board body 10 is flush with the edge of the first board body 10. Specifically, the edge of the flexible substrate 21 in the flexible circuit layer 30 may be flush with the edge of the rigid board 120 in the first board body 10. Alternatively, the edges of the flexible substrate 21 and the second metal wiring layer 112 in the flexible circuit layer 30 may be flush with the edge of the rigid board 120.

Combined with FIG. 1 and FIG. 2, from the perspective of the plan view shown in in FIG. 1, the flexible circuit layer 30 in the first board body 10 may be flush with at least one of the upper, lower and left edges of the first board body 10. The edges of the flexible circuit layer 30 in the first board body 10 may also be flush with the upper, lower and left edges of the first board body 10.

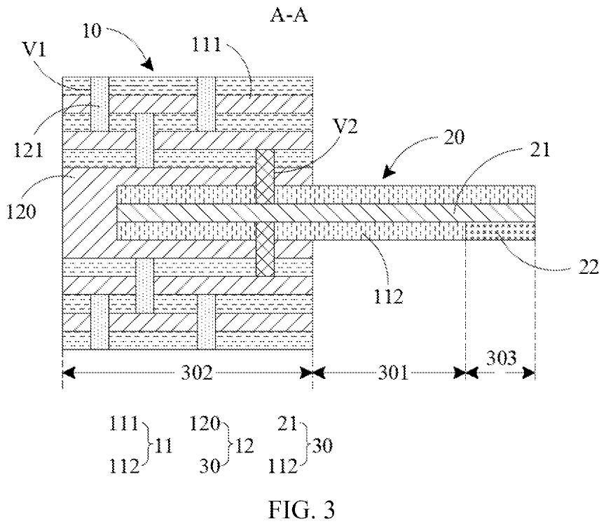

In one of the embodiments, as shown in FIG. 3, FIG. 3 is a schematic cross-sectional view of a second circuit board along the A-A direction according to an embodiment of the present application. It should be noted that the structure of the second circuit board shown in FIG. 3 is substantially the same as that of the first circuit board shown in FIG. 2. The difference is that, in the second circuit board shown in FIG. 3, the edge of the flexible circuit layer 30 located in the first board body 10 is retracted and disposed in the first board body 10 and is connected with the first board body 10. The edge of the board body 10 maintains a preset distance. The preset distance can be set according to actual needs, and is not limited here.

Combined with FIG. 1 and FIG. 3, in the perspective of the plan view shown in FIG. 1. The edge of the flexible circuit layer 30 in the first board body 10 may maintain a preset distance as shown in FIG. 3 from at least one of the upper, lower and left edges of the first board body 10. The edge of the flexible circuit layer 30 in the first board body 10 may also maintain a preset distance from the upper, lower and left edges of the first board body 10 as shown in FIG. 3.

Further, in the thickness direction of the first board body 10, the flexible circuit layer 30 is relatively located in the middle position of the first board body 10.

As shown in FIG. 2, the first board body 10 has 7 layers of interlayer substrates 12 and a total of 8 layers of metal wiring layers 11 respectively disposed on each of the interlayer substrates 12. In order from top to bottom, the fourth interlayer substrate is the flexible circuit layer 30, and the other interlayer substrates are the rigid boards 120. A first metal wiring layer 111 is provided on the side of the rigid board 120 away from the flexible circuit layer 30. The flexible circuit layer 30 is disposed between the third interlayer substrate and the fourth interlayer substrate. The flexible circuit layer 30 has the flexible substrate 21 and second metal wiring layers 112 located on the upper and lower sides of the flexible substrate 21.

Further, the flexible second board body 20 includes at least one layer of the flexible circuit layer 30. One end of the flexible circuit layer 30 is set as a pressing part 302. The pressing part 302 of the flexible circuit layer 30 is disposed in the first board body 10.

As shown in FIG. 2, in an embodiment of the present application, the flexible circuit layer 30 has a main body part 301 and a pressing part 302 located at one end of the main body part 301. The pressing part 302 of the flexible circuit layer 30 is disposed in the first board body 10.

Further, via holes are formed on the interlayer substrate 12, and the metal wiring layers 11 located in different layers communicate with each other through the via holes.

As shown in FIG. 2, the via holes include a first via hole V1 and a second via hole V2.

In the process of preparing the circuit board, a plurality of first via holes V1 passing through at least one layer of the rigid board 120 may be formed by means of laser drilling. The first via hole V1 may be filled with a metal conductive material to form a first connection part 121. In this way, the first metal wiring layers 111 located on the same side of the flexible circuit layer 30 and located on different rigid boards 120 are electrically connected through the first vias V1 passing through the rigid boards 120.

In the process of preparing the circuit board, the upper and lower sides of the pressing part of the flexible circuit layer 30 and the rigid board 120 in the first board body 10 may be pressed together by hot pressing. A second via hole V2 penetrating the at least one layer of the rigid board 120 is formed on the at least one layer of the rigid board 120 adjacent to the flexible circuit layer 30 by means of mechanical drilling. Then, the connection part 121 is formed in the second via hole V2 by electroplating or other methods. In this way, the first metal wiring layer 111 on the rigid board 120 in the first board body 10 is electrically connected to the second metal wiring layer 112 in the flexible circuit layer 30. In this way, the flexible circuit layer 30 can be integrated into the manufacturing process of the first board body 10, so that the connectors or binding terminals required for the electrical connection between the first board body 10 and the second board body 20 can be omitted.

Further, the materials of the first connection part 121 and the second connection part 122 may include copper, aluminum, nickel, tin or other metal materials with ductile properties. In the embodiment of the present application, the material of the first connection part 121 and the second connection part 122 may be solid copper pillars as shown in FIG. 2 or FIG. 3.

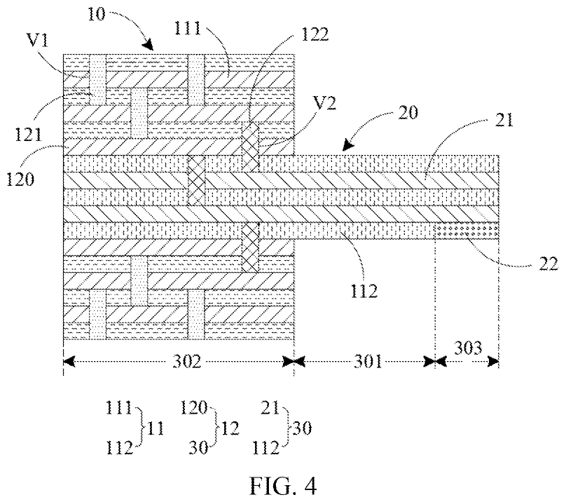

As shown in FIG. 4, FIG. 4 is a schematic cross-sectional view of a third circuit board along the A-A direction according to an embodiment of the present application. It should be noted that the structure of the third circuit board shown in FIG. 4 is substantially the same as that of the first circuit board shown in FIG. 2. The difference is that the third circuit board shown in FIG. 4 includes two flexible circuit layers 30. The two flexible circuit layers 30 are stacked in sequence. The two flexible circuit layers 30 both include a flexible substrate 21 and a second metal wiring layer 112 located on both sides of the flexible substrate 21. The second metal wiring layers 112 between two adjacent layers of the flexible circuit layers 30 may be electrically connected through second via holes V2 penetrating at least one layer of the flexible substrate 21. The second metal wiring layer 112 in the flexible circuit layer 30 may also be electrically connected to the first metal wiring layer 111 on the rigid board 120 through other via holes.

In practical applications, the number of flexible circuit layers 30 in the circuit board is not limited to one or two layers in the above embodiments. The circuit board may also have three or more flexible circuit layers, which are not limited here.

Further, an opposite end of the flexible circuit layer where the pressing part is located is set as a binding part, and the binding part of the flexible circuit layer is suspended before binding an external device.

As shown in FIG. 2, in an embodiment shown in FIG. 2, a binding part 303 is provided at one end of the main body part 301 of the flexible circuit layer 30 away from the pressing part 302. The binding part 303 may be provided with a plurality of first binding terminals 22 for binding. The first binding terminal 22 and the second metal wiring layer 112 in the flexible circuit layer 30 may be formed by using the same layer of metal. The binding part 303 is suspended before binding the external device.

Further, the second board body includes two or more sub-boards arranged at intervals along the same direction, the pressing parts of each of the sub-boards are connected to form a board, and the binding parts of each of the sub-boards are arranged independently of each other.

As shown in FIG. 1, the second board body 20 may include six sub-boards 201 spaced along the same direction. The structure of each of the sub-boards 201 may be the same as the structure of the second board body 20 in the circuit board provided in the embodiment of the present application.

It should be noted that FIG. 1 only illustrates a distribution of the sub-boards 201. The number and size of the sub-boards 201 in FIG. 1 do not represent the number and size of the sub-boards in the circuit board under actual conditions.

According to the circuit board provided by the embodiment of the present invention, a display module adapted to the circuit board is also provided. A border area of the display panel is provided with binding terminals. The binding part of the flexible circuit layer is fixed and electrically connected to the binding terminal of the display panel.

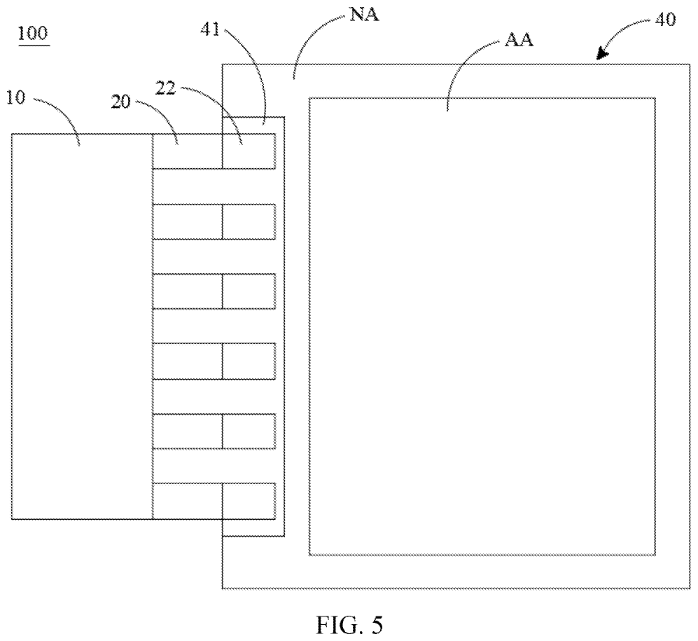

As shown in FIG. 5, FIG. 5 is a schematic structural diagram of a display module according to an embodiment of the present application. The display module 100 includes a display panel 40. The display panel 40 includes a display area AA and a border area NA disposed on a periphery of the display area AA. A second binding terminal 41 is disposed in the border area NA on one side of the display area AA. The first binding terminal 22 of the binding part 303 of the flexible circuit layer 30 is fixed and electrically connected to the second binding terminal 41 of the display panel 40.

The beneficial effects of the embodiments of the present application: compared with the prior art, the circuit board provided by the present invention integrates the flexible circuit board into the preparation process of the printed circuit board. Part of the circuit layers of the flexible circuit board are embedded in the interlayer structure of the printed circuit board and pressed together to realize the combination of the printed circuit board and the flexible circuit board. This avoids the late binding process or the access of electrical connectors, so that the product becomes lighter and thinner and the connection stability is enhanced.

In conclusion, although the present application discloses the preferred embodiments as above, the above preferred embodiments are not intended to limit the present application. Those skilled in the art can make various changes and modifications without departing from the spirit and scope of the present application. Therefore, the protection scope of the present application is based on the scope defined by the claims.

What is claimed is:

1. A circuit board, comprising:
a first board body and a second board body combined with the first board body, wherein the first board body is a rigid board body, the second board body is a flexible board body, the first board body comprises a flexible circuit layer fixedly arranged in the first board body, and the flexible circuit layer comprises a flexible substrate and a metal wiring layer disposed on at least one side of the flexible substrate;
wherein the flexible circuit layer is electrically connected to the metal wiring layer of the first board body and extends to an outside of the first board body, and a part of the flexible circuit layer outside the first board body is any functional layer of the second board body.

2. The circuit board according to claim 1, wherein the first board body comprises a multi-layer interlayer substrate and the metal wiring layer located on the multi-layer interlayer substrate, and the multi-layer interlayer substrate comprises a rigid board and at least one layer of the flexible circuit layer.

3. The circuit board according to claim 2, wherein an edge of the flexible circuit layer located in the first board body is arranged flush with an edge of the first board body or is arranged inwardly in the first board body and maintains a preset distance from the edge of the first board body.

4. The circuit board according to claim 3, wherein in a thickness direction of the first board body, the flexible circuit layer is relatively located in a middle position of the first board body.

5. The circuit board according to claim 2, further comprising a via hole formed on the multi-layer interlayer substrate, wherein metal wiring layers located in different layers are communicated through the via hole.

6. The circuit board according to claim 1, wherein in the multi-layer interlayer substrate, a material of the rigid board is one or a combination of two or more of a phenolic resin, a glass fiber, and an epoxy resin: a substrate material of the flexible circuit layer is a polyimide, a polyester film, a polytetrafluoroethylene, or a polyamide fiber.

7. The circuit board according to claim 2, wherein the second board body comprises at least one layer of the flexible circuit layer, one end of the flexible circuit layer is set as a pressing part, and the pressing part of the flexible circuit layer is fixedly arranged in the first board body.

8. The circuit board according to claim 7, wherein an opposite end of the flexible circuit layer where the pressing part is located is set as a binding part, and the binding part of the flexible circuit layer is suspended before binding an external device.

9. The circuit board according to claim 8, wherein the second board body comprises two or more sub-boards arranged at intervals along a same direction, pressing parts of the sub-boards are connected to form a board, and binding parts of the sub-boards are arranged independently of each other.

10. A display module, comprising:
a display panel; and
a circuit board, wherein the circuit board comprises a first board body and a second board body combined with the first board body, wherein the first board body is a rigid board body, the second board body is a flexible board body, the first board body comprises a flexible circuit layer fixedly arranged in the first board body, and the flexible circuit layer comprises a flexible substrate and a metal wiring layer disposed on at least one side of the flexible substrate;
wherein the flexible circuit layer is electrically connected to the metal wiring layer of the first board body and extends to an outside of the first board body, a part of the flexible circuit layer outside the first board body is any functional layer of the second board body, a border area of the display panel is provided with a binding terminal, and a binding part of the flexible circuit layer is fixed and electrically connected to the binding terminal of the display panel.

11. The display module according to claim 10, wherein the first board body comprises a multi-layer interlayer substrate and the metal wiring layer located on the multi-layer interlayer substrate, and the multi-layer interlayer substrate comprises a rigid board and at least one layer of the flexible circuit layer.

12. The display module according to claim 11, wherein an edge of the flexible circuit layer located in the first board body is arranged flush with an edge of the first board body or is arranged inwardly in the first board body and maintains a preset distance from the edge of the first board body.

13. The display module according to claim 12, wherein in a thickness direction of the first board body, the flexible circuit layer is relatively located in a middle position of the first board body.

14. The display module according to claim 11, further comprising a via hole formed on the multi-layer interlayer substrate, wherein metal wiring layers located in different layers are communicated through the via hole.

15. The display module according to claim 14, wherein the via hole is filled with a metal conductive material, and the metal conductive material comprises any one of copper, aluminum, nickel, and tin.

16. The display module according to claim 10, wherein in the multi-layer interlayer substrate, a material of the rigid board is one or a combination of two or more of a phenolic resin, a glass fiber, and an epoxy resin: a substrate material of the flexible circuit layer is a polyimide, a polyester film, a polytetrafluoroethylene, or a polyamide fiber.

17. The display module according to claim 11, wherein the second board body comprises at least one layer of the flexible circuit layer, one end of the flexible circuit layer is set as a pressing part, and the pressing part of the flexible circuit layer is fixedly arranged in the first board body.

18. The display module according to claim 17, wherein an opposite end of the flexible circuit layer where the pressing part is located is set as a binding part, and the binding part of the flexible circuit layer is suspended before binding an external device.

19. The display module according to claim 18, wherein the second board body comprises two or more sub-boards arranged at intervals along a same direction, pressing parts of the sub-boards are connected to form a board, and binding parts of the sub-boards are arranged independently of each other.

20. The display module according to claim 10, wherein a material of the metal wiring layer is tin, copper, chromium, palladium, nickel, gold, aluminum, or one of alloys of above metal materials.
